(19) United States
(12) Patent Application Publication
(10) Pub. No.: US 2024/0319266 A1
(43) Pub. Date: Sep. 26, 2024

(54) INTEGRATED CIRCUIT

(71) Applicant: LAPIS Technology Co., Ltd., Yokohama (JP)

(72) Inventor: Takahiro YONEDA, Yokohama (JP)

(73) Assignee: LAPIS Technology Co., Ltd., Yokohama (JP)

(21) Appl. No.: 18/607,596

(22) Filed: Mar. 18, 2024

(30) Foreign Application Priority Data
Mar. 20, 2023 (JP) 2023-044772

(51) Int. Cl. G01R 31/30; G01R 31/317

(52) U.S. Cl. CPC G01R 31/3004; G01R 31/31721

(57) ABSTRACT

Provided is an integrated circuit that detects the state of the power supply of the integrated circuit using a logic circuit. An integrated circuit 10 includes an output circuit that outputs an inspection signal; a logic circuit 32 that is supplied with power from a first power supply S1 and outputs a result signal based on the inspection signal and the state of the first power supply S1 in response to the inspection signal being input; and a determination circuit 24 that is supplied with power from a second power supply S2 different from the power supply and determines the state of the logic circuit 32 based on the inspection signal and the result signal respectively input from the output circuit and the logic circuit 32.

### CROSS-REFERENCE TO RELATED APPLICATION

This application claims the priority benefits of Japanese application no. 2023-044772, filed on Mar. 20, 2023. The entirety of the above-mentioned patent application is hereby incorporated by reference herein and made a part of this specification.

### BACKGROUND

### Technical Field

The disclosure relates to an integrated circuit.

### Description of Related Art

Patent Document 1 (Japanese Patent Application Laid-Open No. 2014-163917) discloses a semiconductor device that includes a plurality of power supply inspection circuits for detecting power supply voltage abnormality for each pad which connects internal wiring arranged inside the semiconductor device and other components arranged outside, and a result storage register for storing inspection results indicated by result signals output from the plurality of power supply inspection circuits.

The disclosure provides an integrated circuit that detects the state of the power supply of the integrated circuit using a logic circuit.

### SUMMARY

An integrated circuit according to the first aspect of the disclosure includes an output circuit that outputs an inspection signal; a logic circuit that is supplied with power from a power supply and outputs a result signal based on the inspection signal and a state of the power supply in response to the inspection signal being input; and a determination circuit that is supplied with power from another power supply different from the power supply and determines a state of the logic circuit based on the inspection signal and the result signal respectively input from the output circuit and the logic circuit.

In the integrated circuit according to this aspect, the inspection signal output from the output circuit is output to the logic circuit and the determination circuit. Further, the logic circuit outputs the result signal based on the state of the power supply to the determination circuit. Therefore, in the integrated circuit according to this aspect, the determination circuit is capable of detecting the state of the power supply by determining the state of the logic circuit based on the inspection signal and the result signal.

### BRIEF DESCRIPTION OF THE DRAWINGS

FIG. 1 is a diagram illustrating the integrated circuit according to the first embodiment of the disclosure.

FIG. 2 is a diagram illustrating the integrated circuit according to the first modification of the first embodiment of the disclosure.

FIG. 3 is a diagram illustrating the integrated circuit according to the second modification of the first embodiment of the disclosure.

FIG. 4 is a diagram illustrating the integrated circuit according to the second embodiment of the disclosure.

FIG. 5 is a diagram illustrating the supplied voltage and the delay time in the delay circuit according to the second embodiment of the disclosure.

FIG. 6A and FIG. 6B are diagrams illustrating operations of the clock supply circuit, the first flip-flop circuit, and the second flip-flop circuit in the integrated circuit according to the second embodiment of the disclosure, wherein FIG. 6A is a diagram showing the operation in a state before the delay time of the delay circuit changes, and FIG. 6B is a diagram showing the operation in a state after the delay time of the delay circuit is increased.

FIG. 7A and FIG. 7B are diagrams illustrating operations of the clock supply circuit, the first flip-flop circuit, and the second flip-flop circuit in the integrated circuit according to the second embodiment of the disclosure following FIG. 6A and FIG. 6B, wherein FIG. 7A is a diagram showing the operation in a state before the delay time of the delay circuit changes, and FIG. 7B is a diagram showing the operation in a state after the delay time of the delay circuit is decreased.

FIG. 8 is a diagram illustrating the integrated circuit according to the first modification of the second embodiment of the disclosure.

FIG. 9A and FIG. 9B are diagrams illustrating operations of the clock supply circuit, the first flip-flop circuit, and the second flip-flop circuit in the integrated circuit according to the second modification of the second embodiment of the disclosure, wherein FIG. 9A is a diagram showing the operation before changing the inspection time, and FIG. 9B is a diagram showing the operation when the inspection time is increased.

### DESCRIPTION OF THE EMBODIMENTS

An example of the embodiments of the disclosure will be described hereinafter with reference to the drawings. In each drawing, the same reference numerals are given to the same or equivalent components and parts. Furthermore, the dimensional ratios in the drawings are exaggerated for convenience of illustration and may differ from the actual ratios.

According to the disclosure, it is possible to provide an integrated circuit that detects abnormality in power supply voltage with a logic circuit.

### First Embodiment

### (Configuration)

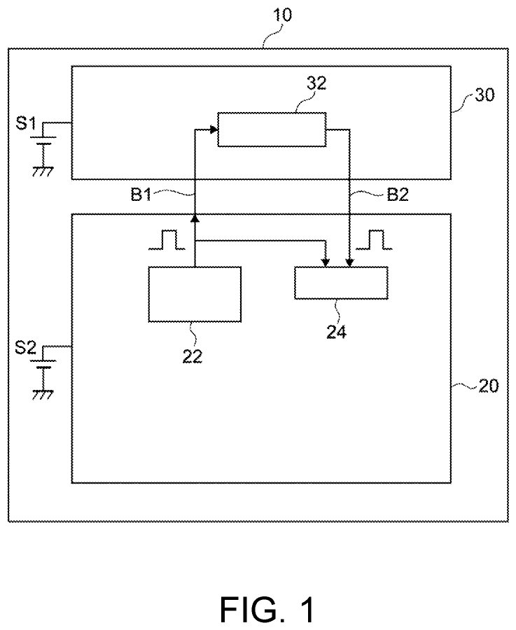

FIG. 1 shows an integrated circuit 10 according to the first embodiment. As shown in FIG. 1, the integrated circuit 10 according to this embodiment includes a reference circuit 20 and an inspection target circuit 30. Furthermore, in the integrated circuit 10 according to this embodiment, the inspection target circuit 30 is supplied with power from a first power supply S1 which is an example of the power supply in the disclosure, and the reference circuit 20 is supplied with power from a second power supply S2 which is an example of another power supply in the disclosure, thereby driving the circuits. Besides, in the integrated circuit 10 according to this embodiment, the reference circuit 20 and the inspection target circuit 30 are electrically connected through a first bus B1 and a second bus B2.

In this embodiment, the first power supply S1 and the second power supply S2 may be any type of power supply that is capable of driving the reference circuit 20 and the inspection target circuit 30, respectively. For example, the first power supply S1 and the second power supply S2 may have the same performance, the first power supply S1 and the second power supply S2 may be DC power supplies but have different voltage values, one may be a DC power supply while the other may be an AC power supply, or the first power supply S1 and the second power supply S2 may have equal voltage values but different current values.

The inspection target circuit 30 includes a logic circuit 32, as shown in FIG. 1. This logic circuit 32 can be any logic circuit such as an AND circuit, a NAND circuit, an OR circuit, a NOR circuit, an EXOR circuit, and a NOT circuit, and in this embodiment, an AND circuit is used as an example. In response to being supplied with power from the first power supply S1 and receiving an inspection signal from an output circuit 22, which will be described later, through the first bus B1, the logic circuit 32 outputs a waveform having a voltage value equivalent to the voltage value of the inspection signal (hereinafter referred to as voltage waveform) as a result signal to the second bus B2. More specifically, the logic circuit 32 outputs a Hi value as the result signal in the case where both the power supplied from the first power supply S1 and the inspection signal input from the first bus B1 exceed a predetermined threshold value. Further, the logic circuit 32 outputs a Low value as the result signal in the case where either the power supplied from the first power supply S1 or the inspection signal input from the first bus B1 is equal to or less than the predetermined threshold value.

Although the Hi value, the Low value, and the predetermined threshold value may be set to any value, the predetermined threshold value may be a value that exceeds the recommended operating voltage for the inspection target circuit 30 to operate.

The reference circuit 20 includes the output circuit 22 that outputs the inspection signal, and a determination circuit 24 that receives the inspection signal and the result signal.

The output circuit 22 outputs the inspection signal to the logic circuit 32 of the inspection target circuit 30 and the determination circuit 24, as shown in FIG. 1. This inspection signal may be any signal that can be supplied to the logic circuit 32 and the determination circuit 24, and as an example, a voltage waveform indicating a binary value of Hi or Low as a voltage is output as the inspection signal. The inspection signal is input to the logic circuit 32 and the determination circuit 24 through the first bus B1.

It should be noted that any waveform may be used as the voltage waveform output as the inspection signal. Examples of the voltage waveform include a pulse wave that rises and falls once, a step wave that remains Hi after rising, and a bit string that has a predetermined combination of Hi and Low.

As shown in FIG. 1, the determination circuit 24 is a circuit that receives the inspection signal from the output circuit 22 through the first bus B1 and the result signal from the logic circuit 32 of the inspection target circuit 30 through the second bus B2. Further, the determination circuit 24 is a circuit that compares the inspection signal and the result signal, and in this embodiment, compares to determine whether the inspection signal and the result signal have the same value.

More specifically, the determination circuit 24 includes a first holding circuit (not shown) connected to the first bus B1 and a second holding circuit (not shown) connected to the second bus B2. The first holding circuit holds Hi in the case where Hi is input as the inspection signal, and the second holding circuit holds Hi in the case where the result signal is input as Hi. Then, the determination circuit 24 compares the inspection signal and the result signal by comparing the values of the first holding circuit and the second holding circuit.

In the above description and FIG. 1, the first bus B1 directly connects the output circuit 22, the determination circuit 24, and the logic circuit 32, but the integrated circuit 10 according to this embodiment is not limited thereto, and the first bus B1 may connect the output circuit 22, the determination circuit 24, and the logic circuit 32 via other elements. Similarly, the second bus B2 directly connects the determination circuit 24 and the logic circuit 32, but the integrated circuit 10 according to this embodiment is not limited thereto, and the second bus B2 may connect the determination circuit 24 and the logic circuit 32 via other elements. Examples of other elements include passive elements such as transformers and resistors, as well as active elements such as transistors and relays.

In the integrated circuit 10 according to this embodiment, the first bus B1 and the second bus B2 that connect the reference circuit 20 and the inspection target circuit 30 may have a configuration in which the current flows (signal is transmitted) only in the direction of the arrow. For example, the first bus B1 in this embodiment may have a configuration in which a diode is provided between the output circuit 22 and the logic circuit 32. In this case, when the wiring in the inspection target circuit 30 is short-circuited to the first bus B1 and power is directly supplied from the first power supply S1 to the first bus B1 on the inspection target circuit 30, the power supplied from the first power supply S1 to the reference circuit 20 through the first bus B1 is cut off.

### (Detection of the State of the Power Supply)

As described above, in this embodiment, the inspection signal is a voltage waveform that indicates a binary value of Hi or Low, and the logic circuit 32 outputs a binary voltage waveform of Hi or Low, which is a voltage waveform equivalent to the inspection signal, as the result signal. Therefore, in this embodiment, in the case where power is supplied to the logic circuit 32 from the first power supply S1, that is, in the case where the state of the power supply supplied to the logic circuit 32 is normal, the inspection signal and the result signal have voltage waveforms indicating equivalent voltage values. It should be noted that, in the disclosure, the “state of the power supply” includes both a state of the first power supply S1 that supplies power to the logic circuit 32 and a state in which power is being supplied to the logic circuit 32.

For example, in the case where the inspection signal indicates Hi, the logic circuit 32 outputs the result signal indicating Hi like the inspection signal, so the inspection signal and the result signal, both of which are Hi, are input to the determination circuit 24. Further, in the case where the inspection signal indicates Low, the logic circuit 32 outputs the result signal indicating Low like the inspection signal, so the inspection signal and the result signal, both of which are Low, are input to the determination circuit 24.

Thus, in the integrated circuit 10 according to this embodiment, in the case where the inspection target circuit 30 is operating normally, the inspection signal and the result signal input to the determination circuit 24 have the same value whether the inspection signal and the result signal are Hi or Low. In other words, in the integrated circuit 10 according to this embodiment, in the case where the inspection target circuit 30 is operating normally, the inspection signal and the result signal input to the determination circuit 24 have the same value whether the inspection signal and the result signal are Hi or Low.

Here, in the integrated circuit 10 according to this embodiment, in the case where the power supply is not normal, for example, in the case where the first power supply S1 fails or the wiring of the inspection target circuit 30 is disconnected and power is not supplied to the inspection target circuit 30, the operation is as follows. First, even if the inspection signal indicates Hi, the logic circuit 32 is not supplied with power, so the result signal does not become Hi. Therefore, in the case where the first power supply S1 fails or the wiring of the inspection target circuit 30 is disconnected and power is not supplied to the inspection target circuit 30, even if the inspection signal is Hi, the result signal input to the determination circuit 24 becomes OV, that is, Low.

In addition, in the case where another power supply is not normal, for example, in the case where the wiring of the inspection target circuit 30 is short-circuited and power continues to be supplied to the first bus B1 in the integrated circuit 10 according to this embodiment, the operation is as follows. First, even if the inspection signal indicates Low, power continues to be supplied to the logic circuit 32 and power is also supplied from the first bus B1, so the result signal does not become Low. Therefore, even if the wiring of the inspection target circuit 30 is short-circuited, power continues to be supplied to the first bus B1, and the inspection signal is Low, the result signal output to the determination circuit 24 becomes Hi.

Thus, in the integrated circuit 10 according to this embodiment, the inspection signal and the result signal output to the determination circuit 24 have different values in the case where the power supply is not normal.

### Action and Effect

As described above, in the integrated circuit 10 according to this embodiment, the inspection signal and the result signal are output to the determination circuit 24. Therefore, the state of the power supply supplied to the logic circuit 32 can be determined by determining whether the inspection signal has the same value as the result signal regardless of whether the inspection signal input to the determination circuit 24 is Hi or Low.

Then, the case where the state of the power supply supplied to the logic circuit 32 is not normal refers to a case where the first power supply S1 fails, a case where the wiring of the inspection target circuit 30 is disconnected, or a case where the wiring of the inspection target circuit 30 is short-circuited and power continues to be supplied to the first bus B1. Furthermore, the case where the state of the power supply supplied to the logic circuit 32 is not normal can also be said to be a case where the state of the integrated circuit 10 is not normal.

Hence, with the integrated circuit 10 according to this aspect, the determination circuit 24 determines the state of the logic circuit 32 based on the inspection signal and the result signal, thereby detecting the state of the power supply using the logic circuit 32.

Further, in order to measure the state of the power supply of the inspection target circuit 30 with the reference circuit 20, it is also conceivable to use a method that determines an analog signal output from the inspection target circuit 30 using an analog circuit included in the reference circuit 20. Nevertheless, in the case where the state of the power supply is determined by outputting an analog signal from the inspection target circuit 30, as the analog circuit is composed of a reference voltage power supply, a resistor, a comparator, etc., the circuit area tends to be large and is susceptible to noise superimposed on the result signal.

However, according to the integrated circuit 10 in this embodiment, the determination circuit 24 determines the state of the power supply of the inspection target circuit 30 based on the inspection signal and the result signal output from the logic circuit 32. Therefore, the inspection signal can be a digital signal that takes a binary value of Hi or Low. Thus, with the integrated circuit 10 according to this aspect, the influence of noise superimposed on the result signal can be reduced, and the integrated circuit 10 can be made small.

Besides, in the integrated circuit 10 according to this embodiment, the reference circuit 20 and the output circuit 22 are supplied with power from the second power supply S2. Thus, with the integrated circuit 10 according to this aspect, the determination circuit 24 and the output circuit 22 can be incorporated into the same circuit, and the integrated circuit 10 can be made small.

Additionally, in the integrated circuit 10 according to this embodiment, the predetermined threshold value at which the logic circuit 32 operates is set to a value exceeding the recommended operating voltage for the inspection target circuit 30 to operate. Therefore, in the case where the output voltage falls below the threshold value due to a malfunction of the first power supply S1, even if other circuits in the inspection target circuit 30 are operating, the logic circuit 32, which is an AND circuit, outputs Low as the result signal. Thus, with the integrated circuit 10 according to this aspect, it is possible to detect the malfunction of the first power supply S1 even if the inspection target circuit 30 is operating.

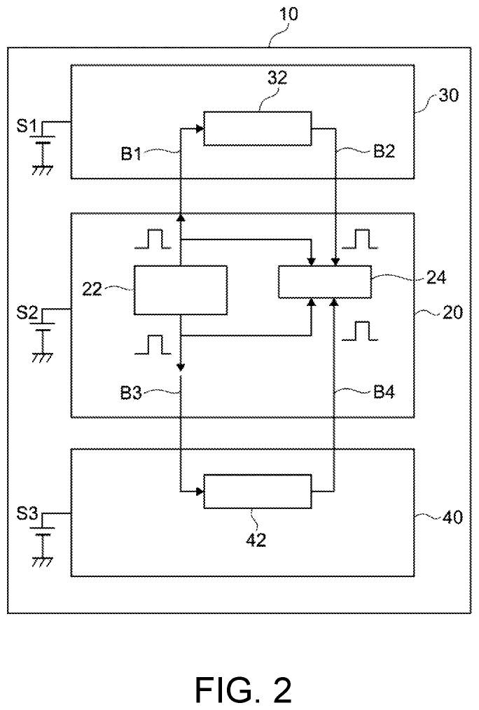

Next, the first modification of this embodiment will be described with reference to FIG. 2. It should be noted that, in the configuration of the first modification, the same components as those in the integrated circuit 10 according to the first embodiment are denoted by the same reference numerals as in the first embodiment, and detailed description thereof may be omitted.

### (First Modification)

### (Configuration)

FIG. 2 is a diagram illustrating the integrated circuit 10 according to the first modification of the disclosure. As shown in FIG. 2, the integrated circuit 10 according to the first modification further includes a second inspection target circuit 40 and a third power supply S3, compared to the integrated circuit 10 according to the first embodiment.

As shown in FIG. 2, the second inspection target circuit 40 is supplied with power from the third power supply S3. The third power supply S3 is another power supply different from the first power supply S1 and the second power supply S2.

Further, as shown in FIG. 2, the second inspection target circuit 40 includes a second logic circuit 42. The second logic circuit 42 is connected to the output circuit 22 via a third bus B3, and receives an inspection signal from the output circuit 22. In addition, the second logic circuit 42 is connected to the determination circuit 24 via a fourth bus, and outputs a result signal to the determination circuit 24. That is, the second logic circuit 42 included in the second inspection target circuit 40 has the same configuration as the logic circuit 32 included in the detection circuit.

As shown in FIG. 2, in the integrated circuit 10 according to the first modification, the reference circuit 20 outputs the inspection signal to the logic circuit 32 through the first bus B1 and to the second logic circuit 42 through the third bus B3, respectively. In other words, in the integrated circuit 10 according to the first modification, the output circuit 22 outputs the inspection signal to each of the logic circuit 32 and the second logic circuit 42 as a plurality of logic circuits.

Moreover, in the integrated circuit 10 according to the first modification, the logic circuit 32 outputs the inspection signal to the determination circuit 24 through the second bus B2, and the second logic circuit 42 outputs the inspection signal to the determination circuit 24 through the fourth bus. In other words, the logic circuit 32 and the second logic circuit 42 are connected in parallel to the determination circuit 24.

The other configurations are similar to those in the integrated circuit 10 according to the first embodiment.

### Action and Effect

In the integrated circuit 10 according to this embodiment, the inspection signal, the result signal output from the logic circuit 32, and the result signal output from the second logic circuit 42 are input to the determination circuit 24. Further, the determination circuit 24 determines the state of the logic circuit 32 and the state of the second logic circuit 42 based on a plurality of result signals output from respective logic circuits 32 in a manner similar to the integrated circuit 10 according to the first embodiment.

Thus, with the integrated circuit 10 according to this aspect, the states of a plurality of logic circuits 32 connected in parallel to the determination circuit 24 can be determined based on the inspection signal and the result signal.

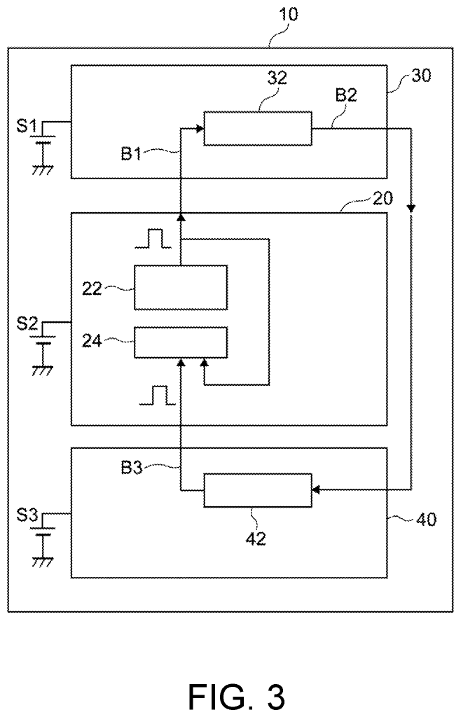

Next, the second modification of this embodiment will be described with reference to FIG. 3. It should be noted that, in the configuration of the second modification, the same components as those in the integrated circuit 10 according to the first embodiment are denoted by the same reference numerals as in the first embodiment, and detailed description thereof may be omitted.

### (Second Modification)

### (Configuration)

FIG. 3 is a diagram illustrating the integrated circuit 10 according to the second modification of the disclosure. As shown in FIG. 3, the integrated circuit 10 according to the second modification further includes a second inspection target circuit 40 and a third power supply S3, compared to the integrated circuit 10 according to the first embodiment.

As shown in FIG. 3, the second inspection target circuit 40 is supplied with power from the third power supply S3. The third power supply S3 is another power supply different from the first power supply S1 and the second power supply S2.

Further, as shown in FIG. 3, the second inspection target circuit 40 includes a second logic circuit 42. The second logic circuit 42 is connected to the logic circuit 32 via a third bus B3, and receives a result signal from the logic circuit 32 as an inspection signal. In addition, the second logic circuit 42 is connected to the determination circuit 24 via the third bus B3, and outputs a result signal to the determination circuit 24.

Here, as shown in FIG. 3, in the integrated circuit 10 according to the second modification, the inspection signal and the result signal are output from the reference circuit 20 to the logic circuit 32 through the first bus B1, and then from the logic circuit 32 to the second logic circuit 42 through the second bus B2. In other words, in the integrated circuit 10 according to the second modification, the logic circuit 32 and the second logic circuit 42 are connected in series. Besides, in other words, in the integrated circuit 10 according to the second modification, the output circuit 22 outputs the inspection signal to the logic circuit 32, which is the first in the order, and the second logic circuit 42, which is the last in the order, outputs the result signal to the determination circuit 24.

The other configurations are similar to those in the integrated circuit 10 according to the first embodiment.

### Action and Effect

In the integrated circuit 10 according to this embodiment, the inspection signal and the result signal output from the second logic circuit 42 are input to the determination circuit 24.

Here, in the case where the states of the power supplies of the inspection target circuit 30 and the second inspection target circuit 40 are normal, the inspection signal and the result signal have the same value, as in the integrated circuit 10 according to the first embodiment. On the other hand, in the case where the state of the power supply of one or both of the inspection target circuit 30 and the second inspection target circuit 40 is not normal, the inspection signal and the result signal have different values, as in the integrated circuit 10 according to the first embodiment.

Thus, with the integrated circuit 10 according to this aspect, the states of a plurality of logic circuits 32 connected in series to the determination circuit 24 can be determined based on the inspection signal and the result signal.

### (Other Modifications)

Although the integrated circuit 10 has only one determination circuit 24 in the reference circuit 20 in the above description, the configuration according to this embodiment is not limited thereto. For example, in the case where the integrated circuit 10 includes a plurality of inspection target circuits 30 and logic circuits 32 as in the first modification, the integrated circuit 10 may have a plurality of determination circuits, so as to input the result signals output from the plurality of logic circuits 32 to the respective determination circuits 24. In this case, the same action and effect as those brought by the integrated circuit 10 according to the first embodiment can also be achieved for each of the plurality of inspection target circuits 30.

Furthermore, although the logic circuit 32 is an AND circuit in the above description, the configuration of the integrated circuit 10 according to this embodiment is not limited thereto. That is, any circuit such as a NAND circuit, an OR circuit, a NOR circuit, an EXOR circuit, and a NOT circuit can be used instead of an AND circuit. For example, in the case of using a NOT circuit as the logic circuit 32, when the first power supply S1 is normal, the values of the inspection signal and the result signal are different, but in the case where the first power supply S1 fails or the wiring is disconnected, the result signal indicates a value of Low regardless of the value of the inspection signal. According to this, even in the case of using a NOT circuit as the logic circuit 32, it is still possible to detect a failure of the first power supply S1 or disconnection of the wiring by comparing the values of the inspection signal and the result signal when the first power supply S1 is normal. Similarly, it is possible to detect a failure of the first power supply S1 or disconnection of the wiring, for example, using an OR circuit. Also, if a NAND circuit is used, the determination circuit 24 in the above description can detect that the state of the power supply is normal in the case where the values of the inspection signal and the result signal do not match. For other circuits, the same action and effect as in this embodiment can be achieved by variously changing the comparison method in the determination circuit 24.

Furthermore, in the above description, the predetermined threshold value is set to a value exceeding the recommended operating voltage for the inspection target circuit 30 to operate, but the configuration according to this embodiment is not limited thereto. That is, the predetermined threshold value may be set to a value equal to or less than the recommended operating voltage for the inspection target circuit 30 to operate as long as the predetermined threshold value is greater than the value of noise superimposed on the inspection signal.

Moreover, in the above description, the output circuit 22 is included in the reference circuit 20, but the configuration according to this embodiment is not limited thereto. That is, the output circuit 22 may be included in the inspection target circuit 30 instead of the reference circuit 20. In other words, the output circuit 22 according to this embodiment may be supplied with power from the first power supply S1 rather than from the second power supply S2. In this case, the determination circuit 24 may detect that the state of the power supply of the inspection target circuit 30 supplied with power from the first power supply S1 is not normal by determining that no signal is output from the output circuit 22.

Further, in the above description, only the reference circuit 20 of the integrated circuit 10 has the output circuit 22 and the determination circuit 24, but the configuration according to this embodiment is not limited thereto. For example, the determination circuit 24 may also be provided in the inspection target circuit 30, and the determination circuits 24 provided in each of the inspection target circuit 30 and the reference circuit 20 may mutually detect the state of the power supply.

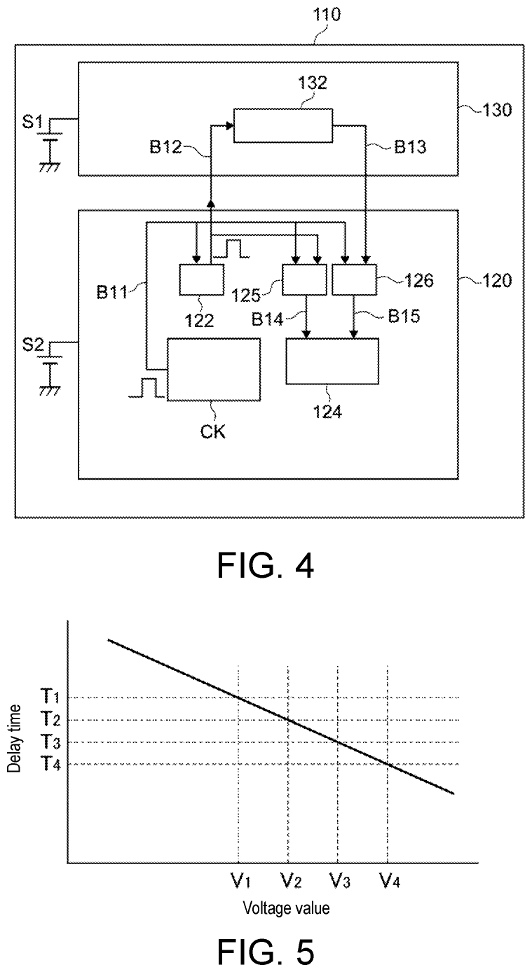

Next, the second embodiment of the disclosure will be described with reference to FIG. 4 to FIG. 7A and FIG. 7B as appropriate. It should be noted that, in the configuration of the second embodiment, the same components as those in the integrated circuit 10 according to the first embodiment and the modifications thereof are denoted by the same reference numerals as in the first embodiment, and detailed description thereof may be omitted.

### Second Embodiment

### (Configuration)

FIG. 4 shows an integrated circuit 110 according to the second embodiment of the disclosure. As shown in FIG. 4, the integrated circuit 110 according to this embodiment includes a clock supply circuit CK, a reference flip-flop circuit 122, a first flip-flop circuit 125, and a second flip-flop circuit 126 in a reference circuit 120. Furthermore, the integrated circuit 110 according to this embodiment includes a delay circuit 132, which is an example of the logic circuit 32, in the inspection target circuit 130.

In the integrated circuit 110 according to this embodiment, the delay circuit 132 is connected to the reference flip-flop circuit 122 through a second bus B12, and connected to the second flip-flop circuit 126 through a third bus B13.

In response to receiving an inspection signal through the second bus B12, the delay circuit 132 according to this embodiment outputs a result signal similar to the result signal of the integrated circuit 10 according to the first embodiment after a delay time based on the voltage of the first power supply S1 elapses. The delay circuit 132 may have any configuration that changes the delay time based on the voltage value of the first power supply S1, but in the case where the voltage value of the first power supply S1 rises, for example, the delay circuit 132 shortens the delay time.

As a specific example, for the delay circuit 132 in which the delay time is T2 when the voltage value of the first power supply S1 indicates V2, the delay time becomes T3, which is shortened, when the voltage value of the first power supply S1 rises to V3, as shown in FIG. 5. Further, when the voltage value of the first power supply S1 falls to V1, the delay time becomes T1, which is lengthened. In this embodiment, as an example, the relationship between the voltage value of the first power supply S1 and the delay time is determined in advance, and the relationship between the voltage value of the first power supply S1 and the delay time is stored in a storage means (not shown). It should be noted that the relationship between the voltage value and the delay time does not need to be stored in the case where the delay time in the voltage value when the first power supply S1 is operating normally is managed or adjusted.

The clock supply circuit CK and the reference flip-flop circuit 122 are an example of the output circuit according to the disclosure. As an example, the clock supply circuit CK outputs a rectangular wave to the reference flip-flop circuit 122, the first flip-flop circuit 125, and the second flip-flop circuit 126 through the first bus B11.

Additionally, in this embodiment, the reference flip-flop circuit 122 outputs an inspection signal to the first flip-flop circuit 125, the second flip-flop circuit 126, and the delay circuit 132 through the second bus B12 in the case where a clock supply signal is output from the first bus B11.

Besides, in this embodiment, the first flip-flop circuit 125 outputs a result signal to the determination circuit 124 through the fourth bus B14 in the case where an inspection signal is output from the second bus B12.

Furthermore, in this embodiment, the second flip-flop circuit 126 outputs a result signal to the determination circuit 124 through the fifth bus B15 in the case where a result signal is output from the third bus B13.

Then, the determination circuit 124 according to this embodiment compares the result signals, which are the values of the first flip-flop circuit 125 and the second flip-flop circuit 126, after an inspection time CT, which will be described later, elapses. That is, the first flip-flop circuit 125 and the second flip-flop circuit 126 according to this embodiment are also part of the determination circuit according to the disclosure.

It should be noted that the reference flip-flop circuit 122, the first flip-flop circuit 125, and the second flip-flop circuit 126 according to this embodiment are, for example, D type flip-flop circuits. That is, the reference flip-flop circuit 122, the first flip-flop circuit 125, and the second flip-flop circuit 126 are reset by a clock signal output from the clock supply circuit CK. Thereby, the reference flip-flop circuit 122, the first flip-flop circuit 125, and the second flip-flop circuit 126 are synchronized.

Furthermore, the reference flip-flop circuit 122 outputs an inspection signal in response to receiving the clock signal. Therefore, the timing at which the reference flip-flop circuit 122 outputs the inspection signal is the timing of start of the inspection time CT, which will be described later. In this embodiment, the inversions of the signals in the first flip-flop circuit 125 and the second flip-flop circuit 126 are used as the result signals output from the respective flip-flop circuits.

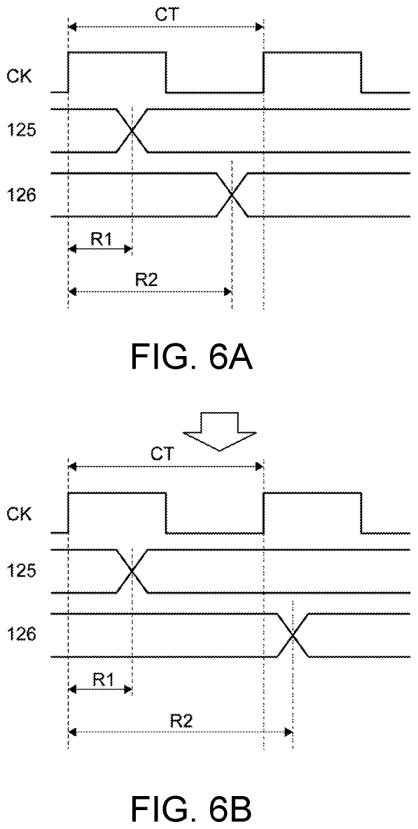

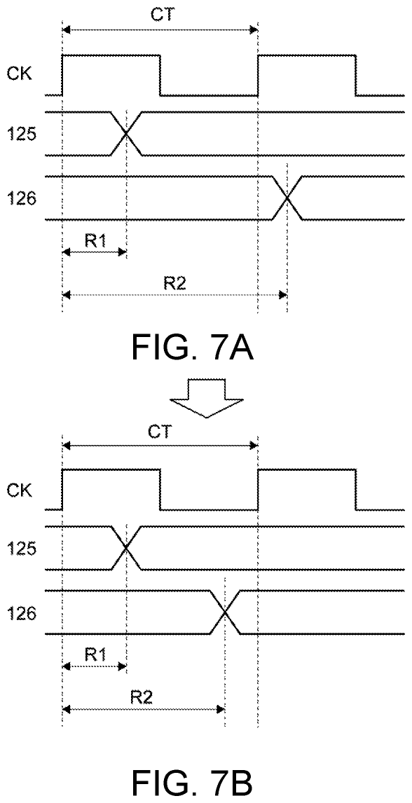

Next, a method of detecting the state of the power supply performed by the integrated circuit 110 according to this embodiment will be described with reference to FIG. 6A, FIG. 6B, FIG. 7A, and FIG. 7B.

### (Detection of the State of the Power Supply)

In the integrated circuit 110 according to this embodiment, the determination circuit 124 determines the state of the power supply based on the inspection time CT which is a predetermined time, and the inspection signals output from both the first flip-flop circuit 125 and the second flip-flop circuit 126. More specifically, the determination circuit 124 determines the state of the power supply based on the inspection signals output from both the first flip-flop circuit 125 and the second flip-flop circuit 126 after input of the inspection time CT. In this embodiment, the inspection time CT is, for example, one period of a rectangular wave output from the clock supply circuit CK, as shown in FIG. 6A and FIG. 6B, for example. However, the inspection time CT is not limited to a period of the rectangular wave output from the clock supply circuit CK, and may be determined by other methods.

As shown in FIG. 4, in the case where the clock signal is output from the clock supply circuit CK to the reference flip-flop circuit 122, the inspection signal is output from the reference flip-flop circuit 122 to the first flip-flop circuit 125. Then, in the case where the inspection signal is input to the first flip-flop circuit 125, the result signal is output from the first flip-flop circuit 125 to the determination circuit 124.

Here, as shown in FIG. 6A and FIG. 6B, the result signal output from the first flip-flop circuit 125 is output to the determination circuit 124 with a delay of a first delay time R1 from the time point when the inspection signal is output from the reference flip-flop circuit 122. This first delay time R1 is a time delayed for transmission of the inspection signal from the reference flip-flop circuit 122 to the first flip-flop circuit 125.

Furthermore, in the case where the inspection signal is output from the reference flip-flop circuit 122 to the delay circuit 132, the result signal is output from the delay circuit 132 to the second flip-flop circuit 126 after a delay time based on the voltage of the first power supply S1 elapses. Then, the result signal is output from the second flip-flop circuit 126 to the determination circuit 124.

Here, as shown in FIG. 6A and FIG. 6B, the result signal output from the second flip-flop circuit 126 is output to the supply circuit with a delay of a second delay time R2 from the time point when the inspection signal is output from the reference flip-flop circuit 122. This second delay time R2 is a time delayed for transmission of the inspection signal from the reference flip-flop circuit 122 to the delay circuit 132, the delay time of the delay circuit 132, and transmission of the result signal from the delay circuit 132 to the second flip-flop circuit 126.

As described above, in this embodiment, the delay time of the delay circuit 132 changes based on the voltage of the first power supply S1. In other words, in the case where the delay time changes, it can be determined that the voltage of the first power supply S1 is changing.

For example, it is assumed that the power supply is normal in the case where the result signal output from the first flip-flop circuit 125 and the result signal output from the second flip-flop circuit 126 are input to the determination circuit 124 within the inspection time CT, as shown in FIG. 6A. Under this condition, if the voltage of the first power supply S1 falls and the second delay time R2 becomes longer, for example, the result signal output from the delay circuit 132 may not reach the second flip-flop circuit 126 within the inspection time CT, as shown in FIG. 6B. In this case, the determination circuit 124 determines that the voltage of the first power supply S1 falls and is not normal as the result signal from the delay circuit 132 does not arrive within the inspection time CT.

Further, for example, it is assumed that the power supply is normal in the case where the result signal output from the first flip-flop circuit 125 is input to the determination circuit 124 within the inspection time CT and the result signal output from the second flip-flop circuit 126 is not input within the inspection time CT, as shown in FIG. 7A. Under this condition, if the voltage of the first power supply S1 rises and the second delay time R2 becomes shorter, for example, the result signal from the delay circuit 132 may reach the second flip-flop circuit 126 within the inspection time CT, as shown in FIG. 7B. In this case, the determination circuit 124 determines that the voltage of the first power supply S1 rises and is not normal as the result signal from the delay circuit 132 arrives within the inspection time CT.

### Action and Effect

Thus, in the integrated circuit 110 according to this aspect, the determination circuit 124 determines the state of the delay circuit 132 based on the inspection signal and the result signal after the inspection time CT elapses.

Therefore, the determination circuit 124 determines the state of the delay circuit 132 based on the inspection signal and the result signal after the inspection time CT elapses, thereby detecting the state of the power supply that supplies power to the delay circuit 132.

Furthermore, in the integrated circuit 110 according to this embodiment, the determination circuit 124 includes the first flip-flop circuit 125 to which the inspection signal is input, and the second flip-flop circuit 126 to which the result signal is input. Therefore, in the determination circuit 124 according to this embodiment, the first flip-flop circuit 125 holds that the inspection signal has been input, and the second flip-flop circuit 126 holds that the result signal has been input. Thus, with the integrated circuit 110 according to this aspect, it is possible to store whether the inspection signal and the result signal are Hi or Low.

This embodiment can also achieve the same effect as the first embodiment. Moreover, the same modifications as the first embodiment can be applied to this embodiment as well.

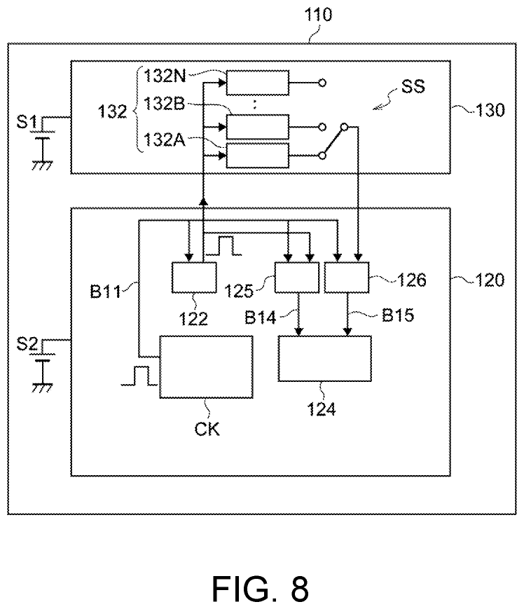

Next, the first modification of this embodiment will be described with reference to FIG. 8 as appropriate. It should be noted that, in the configuration of the first modification, the same components as those in the integrated circuit 110 according to the second embodiment are denoted by the same reference numerals as in the second embodiment, and detailed description thereof may be omitted.

### (First Modification)

### (Configuration)

FIG. 8 is a diagram illustrating the integrated circuit 110 according to the first modification. As shown in FIG. 8, the integrated circuit 110 according to the first modification includes a plurality of delay circuits 132 and a selector SS.

The plurality of delay circuits 132 are, in order, a first delay circuit 132A, a second delay circuit 132B, . . . , and an N^{th} delay circuit 132N. These plurality of delay circuits 132 respectively have different delay times set in order, and for example, the first delay circuit 132A has a shorter delay time than the second delay circuit 132B. Similarly, the plurality of delay circuits 132 are respectively set so that the delay time becomes longer in order. Further, the delay times of these plurality of delay circuits 132 change based on the voltage value of the first power supply S1, similarly to the delay circuit 132 of the second embodiment. It should be noted that, in this modification, the specific number of delay circuits 132 is set as appropriate.

As shown in FIG. 8, the selector SS connects the output side terminals of the plurality of delay circuits 132 and a third bus B13. This selector SS may have any configuration, but as an example, the selector SS is configured to electrically connect the output side terminal of any one of the plurality of delay circuits 132 by a plurality of transistors that are controlled from the outside of the inspection target circuit 30.

The other configurations are similar to those in the integrated circuit 110 according to the second embodiment.

### (Detection of the State of the Power Supply)

In this embodiment, the delay circuit 132 that outputs the result signal to the second flip-flop circuit 126 is selected by changing the connection relationship of the selector SS. Here, as described above, each of the plurality of delay circuits 132 has a different delay time determined in advance. Here, in the integrated circuit 110 according to this modification, the delay circuit 132 that outputs the result signal from the second flip-flop circuit 126 within the inspection time CT is selected from among the plurality of delay circuits 132.

In this case, since the delay time of the selected delay circuit 132 is determined in advance, even if the voltage value of the first power supply S1 changes, the lower limit value of the voltage value of the first power supply S1 can be determined from the delay time of the delay circuit 132 that outputs the result signal within the inspection time CT.

Furthermore, it is assumed that, in the integrated circuit 110 according to this modification, it is possible to select the delay circuit 132 in which no result signal is output from the second flip-flop circuit 126 within the inspection time CT from among the plurality of delay circuits 132. In this case, since the delay time of the selected delay circuit 132 is determined in advance, even if the voltage value of the first power supply S1 changes, the upper limit value of the voltage value of the first power supply S1 can be determined from the delay time of the delay circuit 132 which does not output a result signal within the inspection time CT.

### Action and Effect

Thus, the delay circuit 132 whose delay time based on the voltage of the power supply reaches a predetermined time can be obtained by selecting one of the delay circuits 132. Therefore, in the integrated circuit 110 according to this modification, even if the voltage of the power supply supplied to the delay circuit 132 changes, the voltage of the power supply can be determined based on the result signal output from the delay circuit 132 whose delay time reaches a predetermined time.

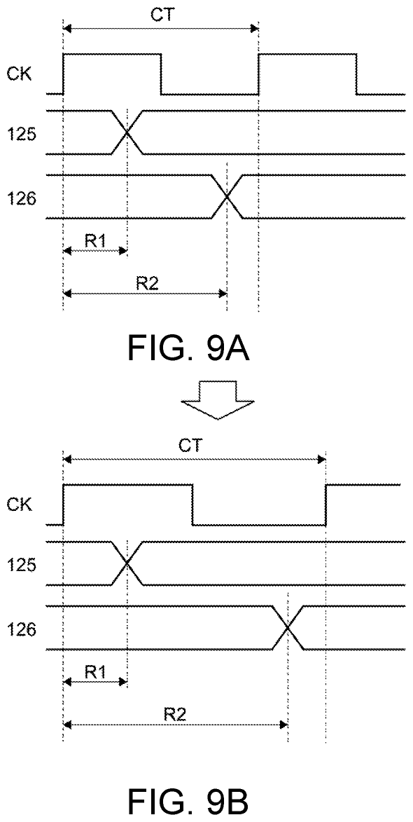

Next, the second modification of this embodiment will be described with reference to FIG. 9A and FIG. 9B as appropriate. It should be noted that, in the configuration of the second modification, the same components as those in the integrated circuit 110 according to the second embodiment are denoted by the same reference numerals as in the second embodiment, and detailed description thereof may be omitted.

### (Second Modification)

### (Configuration)

In the integrated circuit 110 according to the second modification, the inspection time CT is changeable, compared to the integrated circuit 110 of the second embodiment. More specifically, the frequency of the rectangular wave output from the clock supply circuit CK, that is, the time from the rise to the fall of the voltage in the rectangular wave, is changeable.

The other configurations are similar to those in the integrated circuit 110 according to the second modification.

### (Detection of the State of the Power Supply)

In this embodiment, the length of the inspection time CT is changed and selected as appropriate. Here, as described above, the delay time of the delay circuit 132 changes based on the voltage value of the first power supply S1.

For example, it is assumed that, in the integrated circuit 110 according to this modification, it is possible to output the result signal from the second flip-flop circuit 126 within the inspection time CT by changing the inspection time CT, as shown in FIG. 9A to FIG. 9B, even if the voltage value of the first power supply S1 falls and the delay time becomes longer. In this case, the upper limit value of the voltage value of the first power supply S1 can be determined from the delay time of the delay circuit 132 that outputs the result signal within the changed inspection time CT.

Further, for example, it is assumed that it is possible to prevent the second flip-flop circuit 126 from outputting the result signal within the inspection time CT by changing the inspection time CT even if the voltage value of the first power supply S1 rises and the delay time becomes shorter. In this case, the lower limit value of the voltage value of the first power supply S1 can be determined from the delay time of the delay circuit 132 that outputs the result signal within the changed inspection time CT.

### Action and Effect

Thus, the determination circuit 124 can change the length of the predetermined time. Therefore, by changing the length of the time, it is possible to detect that the delay time of the delay circuit 132 based on the voltage of the power supply has reached the changed time. Thus, in the integrated circuit 110 according to this aspect, even if the voltage of the power supply supplied to the delay circuit 132 changes, the voltage of the power supply can be determined from the inspection signal and the changed predetermined time.

### (Other Modifications)

Although the first flip-flop circuit 125, the second flip-flop circuit 126, and the reference flip-flop circuit 122 in the above description are all D type flip-flop circuits, the flip-flop circuits in this embodiment are not limited thereto. For example, RS type, JK type, and T type flip-flop circuits may also be used.

Although the embodiments of the disclosure have been described above with reference to the accompanying drawings, it is clear that a person with ordinary knowledge in the technical field to which the disclosure pertains may come up with various modifications or applications within the scope of the technical idea defined in the claims, and it should be understood that these also naturally fall within the technical scope of the disclosure.

It should be noted that exemplary aspects of the disclosure will be further shown below.

### (Additional Note 1)

An integrated circuit, including:

an output circuit that outputs an inspection signal;

a logic circuit that is supplied with power from a power supply and outputs a result signal based on the inspection signal and a state of the power supply in response to the inspection signal being input; and a determination circuit that is supplied with power from another power supply different from the power supply and determines a state of the logic circuit based on the inspection signal and the result signal respectively input from the output circuit and the logic circuit.

### (Additional Note 2)

The integrated circuit according to additional note 1, including a plurality of the logic circuits that are connected in parallel to the determination circuit and are respectively supplied with power from power supplies different from the power supply,

wherein the output circuit outputs the inspection signal to each of the plurality of logic circuits, and

the determination circuit determines states of the plurality of logic circuits based on the inspection signal and a plurality of the result signals respectively output from the plurality of logic circuits.

### (Additional Note 3)

The integrated circuit according to additional note 1 or 2, including a plurality of the logic circuits that are connected in series and are respectively supplied with power from power supplies different from the power supply,

wherein the output circuit outputs the inspection signal to the first logic circuit in an order among the plurality of logic circuits connected in series, and

the determination circuit determines states of the plurality of logic circuits based on the inspection signal and the result signal output from the last logic circuit in the order among the plurality of logic circuits connected in series.

### (Additional Note 4)

The integrated circuit according to any one of additional notes 1 to 3, wherein the logic circuit is a delay circuit in which a delay time changes based on a voltage from the power supply, and

the determination circuit determines the state of the logic circuit after a predetermined time elapses since the inspection signal is input.

### (Additional Note 5)

The integrated circuit according to additional note 4, wherein the logic circuit includes a plurality of the delay circuits, and

each of the plurality of delay circuits has a different predetermined delay time.

### (Additional Note 6)

The integrated circuit according to additional note 4 or 5, wherein the determination circuit is capable of changing a length of the predetermined time.

### (Additional Note 7)

The integrated circuit according to any one of additional notes 1 to 6, wherein the output circuit is supplied with power from the another power supply.

### (Additional Note 8)

The integrated circuit according to any one of additional notes 1 to 7, wherein the determination circuit includes a first flip-flop circuit to which the inspection signal is input, and a second flip-flop circuit to which the result signal is input.

What is claimed is:

1. An integrated circuit, comprising:
an output circuit that outputs an inspection signal;
a logic circuit that is supplied with power from a power supply and outputs a result signal based on the inspection signal and a state of the power supply in response to the inspection signal being input; and
a determination circuit that is supplied with power from another power supply different from the power supply and determines a state of the logic circuit based on the inspection signal and the result signal respectively input from the output circuit and the logic circuit.

2. The integrated circuit according to claim 1, comprising a plurality of the logic circuits that are connected in parallel to the determination circuit and are respectively supplied with power from power supplies different from the power supply,
wherein the output circuit outputs the inspection signal to each of the plurality of logic circuits, and
the determination circuit determines states of the plurality of logic circuits based on the inspection signal and a plurality of the result signals respectively output from the plurality of logic circuits.

3. The integrated circuit according to claim 1, comprising a plurality of the logic circuits that are connected in series and are respectively supplied with power from power supplies different from the power supply,
wherein the output circuit outputs the inspection signal to the first logic circuit in an order among the plurality of logic circuits connected in series, and
the determination circuit determines states of the plurality of logic circuits based on the inspection signal and the result signal output from the last logic circuit in the order among the plurality of logic circuits connected in series.

4. The integrated circuit according to claim 1, wherein the logic circuit is a delay circuit in which a delay time changes based on a voltage from the power supply, and
the determination circuit determines the state of the logic circuit after a predetermined time elapses since the inspection signal is input.

5. The integrated circuit according to claim 4, wherein the logic circuit comprises a plurality of the delay circuits, and
each of the plurality of delay circuits has a different predetermined delay time.

6. The integrated circuit according to claim 4, wherein the determination circuit is capable of changing a length of the predetermined time.

7. The integrated circuit according to claim 1, wherein the output circuit is supplied with power from the another power supply.

8. The integrated circuit according to claim 1, wherein the determination circuit comprises a first flip-flop circuit to which the inspection signal is input, and a second flip-flop circuit to which the result signal is input.
